(19) United States
(12) Patent Application Publication
(10) Pub. No.: US 2012/0199859 A1
(43) Pub. Date: Aug. 9, 2012

(54) ELECTROLUMINESCENT DISPLAY APPARATUS

(75) Inventors: Noriyuki Shikina, Ichihara-shi (JP); Noa Sumida, Chiba-shi (JP); Yuushi Ichinose, Chiba-shi (JP)

(73) Assignee: CANON KABUSHIKI KAISHA, Tokyo (JP)

(21) Appl. No.: 13/364,023

(22) Filed: Feb. 1, 2012

(30) Foreign Application Priority Data
Feb. 4, 2011 (JP) 2011-022852
Nov. 29, 2011 (JP) 2011-260906

(51) Int. Cl. H01L 51/52

(52) U.S. Cl. 257/98; 257/40; 257/E51.018

(57) ABSTRACT

A display apparatus includes an organic electroluminescent element, a protective layer provided in contact with the organic electroluminescent element and configured to cover the organic electroluminescent element, and a condenser lens provided in contact with the protective layer and on a light output side of the organic electroluminescent element. The condenser lens includes a convex surface having a sloping angle θ_{S} that satisfies a predetermined mathematical condition.

### BACKGROUND OF THE INVENTION

1. Field of the Invention

The present invention relates to a display apparatus including an organic electroluminescent element.

2. Description of the Related Art

In recent years, significant advances have been made in the field of display apparatuses including organic electroluminescent (EL) elements. An organic EL element includes an anode, an organic compound layer including a luminescent layer, and a cathode. Holes and electrons are injected into the luminescent layer from the anode and the cathode, respectively. With energy released during electron-hole recombination, the luminescent layer emits light.

One of objectives in forming an organic electroluminescent element with an organic compound layer including a luminescent layer is to improve light extraction efficiency. To that end, an organic EL device including a lens array provided on a luminescent surface side of organic EL elements has been previously proposed. See Japanese Patent Laid-Open No. 2004-39500.

In the organic EL device disclosed by Japanese Patent Laid-Open No. 2004-39500, however, light rays including obliquely emitted light rays are condensed in such a manner as to travel toward the front. Therefore, the brightness in the forward direction is improved, whereas the brightness in oblique directions is reduced significantly. Consequently, the resultant viewing angle is narrow.

### SUMMARY OF THE INVENTION

At least one embodiment of the present invention provides a display apparatus in which light extraction efficiency is improved while a wide viewing angle is maintained.

According to an aspect of the present invention, a display apparatus includes a display apparatus includes an organic electroluminescent element, a protective layer provided in contact with the organic electroluminescent element and configured to cover the organic electroluminescent element, and a condenser lens provided in contact with the protective layer and on a light output side of the organic electroluminescent element, the condenser lens having a convex surface opposite with respect to the organic electroluminescent element. At a point on the convex surface where light emitted from the organic electroluminescent element is incident on the convex surface of the condenser lens, the condenser lens satisfies the following expression:

sin [θ_{S}−Arcsin {(n₁/n₂)×sin(θ_{S}−θ)}]≧1/n₂

where θdenotes an emission angle of light emitted from the organic electroluminescent element and being incident on the convex surface of the condenser lens, θ_{S} denotes a sloping angle of the convex surface of the condenser lens at a point where the light emitted at the emission angle θ from the organic electroluminescent element is incident, n₁ denotes a refractive index of the condenser lens, and n₂ denotes a refractive index of a medium provided across the condenser lens from the organic electroluminescent element.

According to the above aspect of the present invention, a display apparatus in which light extraction efficiency is improved while sufficient viewing angle characteristics are maintained is obtained.

Further features of the present invention will become apparent from the following description of exemplary embodiments with reference to the attached drawings.

### BRIEF DESCRIPTION OF THE DRAWINGS

FIG. 1 is a sectional view illustrating part of a display apparatus according to an embodiment of the present invention.

FIGS. 2A to 2E illustrate a method of manufacturing the display apparatus according to the embodiment of the present invention.

FIG. 3 is a sectional view illustrating part of a display apparatus according to another embodiment of the present invention.

FIGS. 4A to 4D illustrate a method of manufacturing a display apparatus according to Example 2 of the present invention.

### DESCRIPTION OF THE EMBODIMENTS

### Organic EL Display Apparatus

A display apparatus according to an embodiment of the present invention will now be described with reference to the drawings.

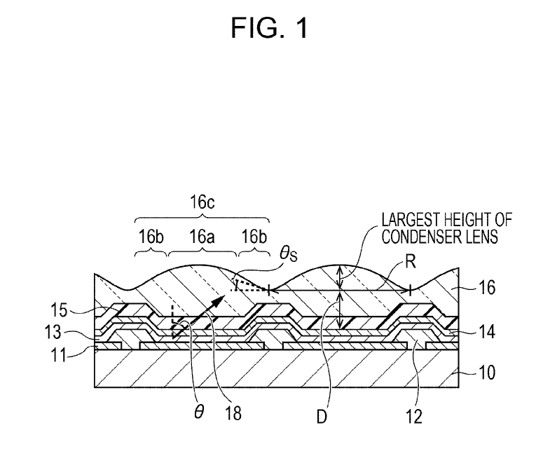

FIG. 1 is a sectional view illustrating part of the display apparatus according to the embodiment of the present invention. The display apparatus is of a top-emission type in which light emitted from organic electroluminescent (EL) elements provided on a substrate is extracted in the upward direction in FIG. 1.

The display apparatus according to the embodiment of the present invention includes a substrate 10 and a plurality of pixels arranged in a matrix on the substrate 10 and thus forming a display area. As used herein, a pixel refers to an area corresponding to one light-emitting element. In the embodiment of the present invention, one organic EL element as a light-emitting element is provided for each of the plurality of pixels. The organic EL elements are separated from one another by a partition member 12. The organic EL elements each include a pair of electrodes, i.e., an anode 11 and a cathode 14, and an organic compound layer 13 interposed between the electrodes and including a luminescent layer (the organic compound layer 13 is hereinafter referred to as the organic EL layer 13). Specifically, a pattern of anodes 11 corresponding to the respective pixels is provided on the substrate 10, the organic EL layer 13 is provided over the pattern of anodes 11, and the cathode 14 is provided over the organic EL layer 13.

The anodes 11 are made of a conductive metal material, such as silver (Ag), having high reflectance. Each of the anodes 11 may be a stack including a layer made of the foregoing metal material and a layer made of a transparent conductive material, such as indium-tin-oxide (ITO) or IZO (a registered trademark used for Chemicals For Industrial Use and owned by Idemitsu Kosan Co., Ltd.), which are considered to provide a superior hole-injection characteristic.

The cathode 14 covers all of the plurality of organic EL elements and has a semireflective or light-transmissive characteristic that allows light from the luminescent layers to be extracted therethrough to the outside of the organic EL elements. Specifically, if the cathode 14 is semireflective so as to increase the interference effect inside the organic EL elements, the cathode 14 is provided in the form of a 2- to 50-nm-thick layer of a conductive metal material, such as Ag or AgMg, having a superior electron-injection characteristic. The term “semireflective characteristic” refers to a characteristic of reflecting some rays of light emitted in the organic EL elements and allowing other rays of the light to be transmitted therethrough, specifically, a characteristic corresponding to a reflectance of 20 to 80% with respect to visible light. The term “light-transmissive characteristic” refers to a characteristic corresponding to a transmittance of 80% or higher with respect to visible light.

The organic EL layer 13 includes one layer or a plurality of layers including at least a luminescent layer. For example, the organic EL layer 13 includes four layers of a hole transport layer, a luminescent layer, an electron transport layer, and an electron injection layer, or three layers of a hole transport layer, a luminescent layer, and an electron transport layer. The organic EL layer 13 may be made of a publicly known material.

The substrate 10 is provided with pixel circuits configured to drive the organic EL elements independently of one another. The pixel circuits include a plurality of transistors (not illustrated). The substrate 10 having the transistors is covered with an interlayer dielectric film (not illustrated) having contact holes allowing electrical connection between the transistors and the anodes 11. The interlayer dielectric film is covered with a planarization film (not illustrated) that absorbs the ruggedness of a surface formed of the pixel circuits and flattens the rugged surface.

The cathode 14 is covered with a first protective layer 15 provided in contact with the organic EL elements and thus protecting the organic EL layer 13 from oxygen and moisture in the air. In other words, the first protective layer 15 covers the cathode 14 and the organic EL layer 13 so as to prevent exposure of the EL layer 13 to environmental agents, such as oxygen or moisture.

The first protective layer 15 is made of an inorganic material such as silicon oxide, silicon nitride, silicon oxynitride, or alumina. The first protective layer 15 may have such a characteristic as to relax the stress occurring when a resin material, described below, is hardened. The first protective layer 15 has a thickness of, for example, 0.1 μm or greater and 10 μm or smaller and is formed by chemical vapor deposition (CVD) or the like. The first protective layer 15 may include either one layer made of any of the foregoing inorganic materials or a plurality of layers made of different ones of the foregoing inorganic materials.

The display apparatus according to the embodiment of the present invention further includes a lens member 16 overlying and in contact with the first protective layer 15. The lens member 16 is made of a transparent resin material having a transmittance of, for example, 90% or greater to visible light with a thickness of 10 μm. Examples of such a resin material include thermosetting resin, photo-curable resin, and thermoplastic resin. More specifically, the following can be named: epoxy resin, polyurethane-curable resin, phenolic resin, urea resin, melamine resin, alkyd resin, acrylic reaction resin, and formaldehyde resin. More specifically, the following can be named: silicon resin, epoxy polyamide resin, a mixture of polyester resin and isocyanate prepolymer, a mixture of polyester polyol and polyisocyanate, a mixture of polyurethane and polyisocyanate, polymers or copolymers composed of, as constitutional units, vinyl chloride, vinyl acetate, vinyl alcohol, maleic acid, acrylic acid, acrylate, vinylidene chloride, acrylonitrile, methacrylic acid, methacrylate, styrene, butadiene, ethylene, vinyl butyral, vinyl acetal, vinyl ether, or the like, and rubber resins. As described below, the lens member 16 has lenses. Therefore, the lens member 16 does not have a uniform thickness and has a smallest thickness, i.e., the thickness at the thinnest part, of 1 μm or greater and 50 μm or smaller, for example. The lens member 16 may be formed by application, printing, or the like. The lens member 16 may be made of an inorganic material. The lens member 16 may also function as the first protective layer 15.

The lens member 16 may be covered with a second protective layer (not illustrated). The second protective layer is made of any of the above inorganic materials such as silicon nitride. Such a second protective layer has a thickness of, for example, 0.5 μm or greater and 5.0 μm or smaller and is formed by CVD or the like.

The lens member 16 has an array of condenser lenses 16c on a light-output-side surface (a surface on the upper side in FIG. 1) thereof. Each of the condenser lenses 16c includes a central portion 16a and a peripheral portion 16b that have different curvatures. The condenser lens 16c satisfies Expressions A and B given below at least at one point on the surface thereof. That is, the condenser lens 16c satisfies Expression C given below at least at one point on the surface thereof. Particularly, the condenser lens 16c satisfies Expressions A and B, i.e., Expression C, in the peripheral portion 16b thereof. In other words, the condenser lens 16c according to the embodiment of the present invention is configured such that a sloping angle θ_{S} at a point on the surface thereof satisfies Expressions A and B, i.e., Expression C, with respect to a refractive index n₁ of the condenser lens 16c and a refractive index n₂ of a medium provided across the condenser lens 16c from the organic EL element. The peripheral portion 16b is an outer portion of the condenser lens 16c having a height smaller than half the largest height of the condenser lens 16c.

sin θ₀=(n₁/n₂)×sin(θ_{S}−θ) A

sin(θ_{S}−θ₀)≧1/n₂ B

sin [θ_{S}−Arcsin {(n₁/n₂)×sin(θ_{S}−θ)}]≧1/n₂ C

where θ is an angle defined by the normal to the surface of the organic layer 13 and the direction of light emitted from the organic layer 13, thus θ denotes the emission angle of light 18 emitted from the organic EL element and being incident on the surface of the condenser lens 16c, θ_{S} denotes the sloping angle of the surface of the condenser lens 16c at a point where the light 18 emitted at the emission angle θ from the organic EL element is incident on the surface of the condenser lens 16c, n₁ denotes the refractive index of the condenser lens 16c, and n₂ denotes the refractive index of the medium provided across the condenser lens 16c from the organic EL element. In the configuration illustrated in FIG. 1, the medium provided across the condenser lens 16c from the organic EL element is air, and the refractive index n₂ is therefore 1.0. That is, as used herein “the medium provided across the condenser lens” is the medium beyond the surface of the condenser lens 16c to which the light emitted from the organic EL element is extracted. Furthermore, θ₀ denotes the angle at which the light 18 having entered the condenser lens 16c at the emission angle θ travels after being refracted at the surface of the condenser lens 16c. That is, θ₀ denotes the angle of the light 18 with respect to the normal to the surface of the condenser lens 16c.

Here, θ, which denotes an arbitrary emission angle, is set so as to be, for example, larger than the smallest angle (critical angle θ_{C}) among the emission angles of rays of the light 18 that cannot be extracted without the condenser lens 16c. If the condenser lens 16c, i.e., the lens member 16, is not provided, the first protective layer 15 is in contact with air. In such a case, since the refractive index of the first protective layer 15 is higher than that of the air, rays of the light 18 radiated from the organic EL element into the first protective layer 15 at angles larger than a certain angle (critical angle θ_{C}) are reflected internally at the interface between the first protective layer 15 and the air by the effect of totally internal reflection. The critical angle θ_{C} for the total reflection is given by Expression D below:

θ_{C}=sin⁻¹(n₀/n₃) D

where n₃ denotes the refractive index of the material on the outgoing side (the first protective layer 15), and n₀ denotes the refractive index of the material on the incoming side (the air).

For example, if the first protective layer 15 is made of silicon nitride, the refractive index n₃ of the first protective layer 15 is 2.00 and the refractive index n₀ of the air is 1.00. Therefore, the critical angle θ_{C} is about 30 degrees (=π/6 rad). Hence, the rays of light 18 that are radiated from the organic EL element into the first protective layer 15 at angles of about 30 degrees and larger are not extracted to the outside.

According to the embodiment of the present invention, the diameter of the condenser lens 16c and the distance from the condenser lens 16c to the organic EL element are set such that the condenser lens 16c receives rays of the light 18 radiated at angles larger than the critical angle θ_{C}. Specifically, a diameter R of the condenser lens 16c and a distance D between the condenser lens 16c and the organic EL element satisfy Expression E below:

R≧2D×tan(θ_{C}) E

For example, when θ_{C} is 30 degrees, Expression E comes to R≧1.15D.

If the surface of the lens member 16 has repetitions of peaks and troughs in sectional view as illustrated in FIG. 1, the diameter R of the condenser lens 16c corresponds to the distance between adjacent ones of the troughs.

If one or a plurality of layers, such as the second protective layer, are provided on the lens member 16, the refractive index of the medium provided across the condenser lens 16c from the organic EL element corresponds to the refractive index of a material forming the outermost layer. In such a case, the central portion 16a and the peripheral portion 16b of the condenser lens 16c may not necessarily have different curvatures, and the condenser lens 16c satisfies Expressions A and B given above at least at one point on the surface thereof.

If the condenser lens 16c satisfies Expressions A and B at least at one point on the surface thereof, rays of the light 18 outputted from the condenser lens 16c include rays traveling in the horizontal direction. That is, in the case where the condenser lens 16c is provided, some rays of the light 18 are outputted in oblique directions.

In a case where light emitted from the organic EL element is incident on a certain surface at an angle θ_{A}, let the angle at which the light incident on the certain surface is outputted from another surface parallel to the organic EL element be θ_{B}, and the angle at which the light incident on the certain surface is outputted from a lens surface be θ_{C}. Here, if θ_{B}>θ_{C} holds, such a characteristic is referred to as a condensing characteristic.

The condenser lenses 16c are formed by processing a resin material. Specifically, the condenser lenses 16c are formed by stamping or the like. One condenser lens 16c may be provided for each of the pixels (for each of the organic EL elements). Alternatively, a plurality of condenser lenses 16c may be provided for each of the pixels, or one condenser lens 16c may be provided for a plurality of pixels. To provide the second protective layer in such a manner as to conform to the surface of the lens member 16, the second protective layer is provided as part of the lens member 16, and the condenser lenses 16c are formed on the second protective layer.

With the presence of the condenser lenses 16c, in a case where, for example, one condenser lens 16c is provided for each of the pixels, the light 18 emitted from the organic EL layer 13 is transmitted through the cathode 14, which is transparent, the first protective layer 15, and the lens member 16 in that order, whereby the light 18 is extracted to the outside of each organic EL element.

The condensing characteristic depends on the area of the luminescent surface, the curvature of the condenser lens 16c, and the distance from the luminescent surface to the condenser lens 16c. The condenser lens 16c is to be designed using the foregoing items as parameters.

### Method of Manufacturing Display Apparatus

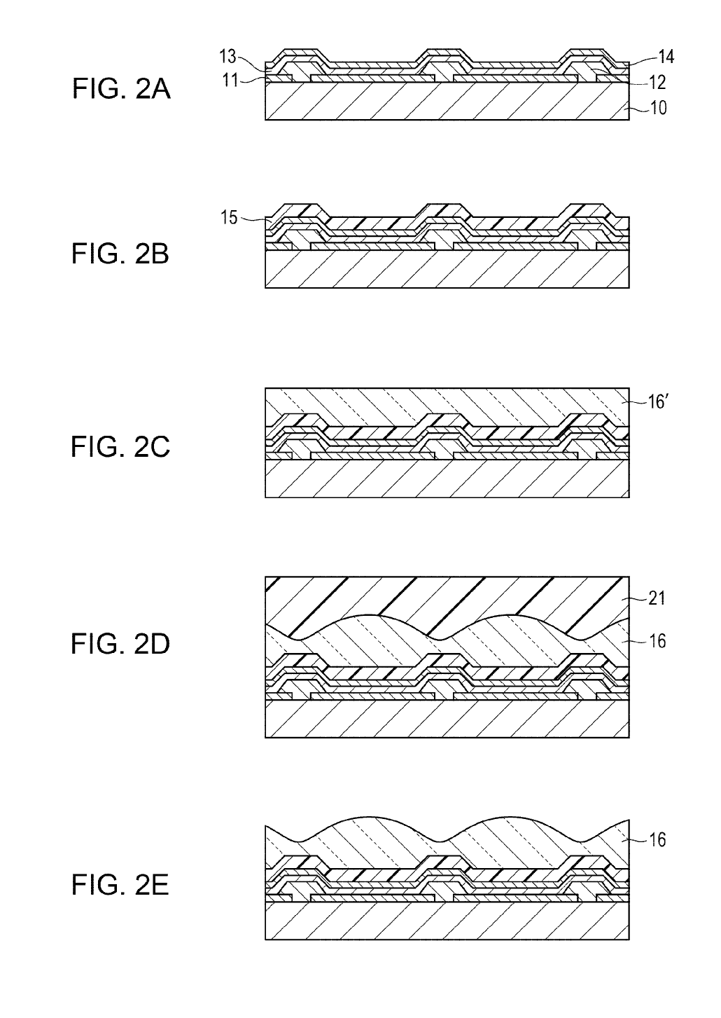

A method of manufacturing the display apparatus according to the embodiment will now be described with reference to FIGS. 2A to 2E. FIGS. 2A to 2E are schematic sectional views illustrating the method of manufacturing the display apparatus according to the embodiment. A process up to the formation of the cathode 14 is publicly known, and description thereof is omitted herein. First, referring to FIG. 2A, a substrate 10 carrying a plurality of top-emission organic EL elements is prepared. Specifically, the substrate 10 has active-matrix pixel circuits. The organic EL elements are provided on the substrate 10 with an interlayer dielectric film and a planarization film interposed therebetween. The organic EL elements are provided in the form of a structure including anodes 11, a partition member 12, an organic EL layer 13, and a cathode 14.

Subsequently, referring to FIG. 2B, a first protective layer 15 is provided over the entirety of the display area. The first protective layer 15 functions as a sealing member that prevents the moisture in the outside air and in a resin material to be provided as a lens member 16 from coming into contact with the organic EL elements. Therefore, the first protective layer 15 has highly light-transmissive and moisture-proof characteristics and is made of, for example, silicon nitride or silicon oxynitride.

Subsequently, referring to FIG. 2C, resin 16′ that is to become the lens member 16 is provided on the first protective layer 15 in such a manner as to spread over the entirety of the display area. The thickness of the resin 16′ is set to about 10 μm to 100 μm so that dust such as residues generated in etching is fully absorbed and a rugged surface of the partition member 12 is flattened. The resin 16′ may be any of thermosetting resin, thermoplastic resin, and photo-curable resin that contain less moisture. If the resin 16′ is thermosetting resin or photo-curable resin, the resin 16′ is provided by spin coating, dispensing, or the like. Alternatively, a film of thermoplastic resin having a thickness of about 10 μm to 100 μm may be pasted onto the first protective layer 15 in a vacuum. Suitable examples of such a resin material include epoxy resin and butyl resin.

Subsequently, referring to FIG. 2D, a die 21 for shaping the resin 16′ into the lens member 16 having condenser lenses 16c is prepared, and the die 21 is pressed into the resin 16′ in such a manner as not to allow the entry of air into the resin 16′.

The die 21 may be made of common metal. If photo-curable resin is employed as the resin 16′, however, the die 21 is made of quartz or the like so that light is transmitted therethrough. To enhance the releasability of the die 21 from the resin 16′, a film of fluoro-resin or the like may be provided on the die 21.

If thermosetting resin is employed as the resin 16′, the resin 16′ is hardened by heating the resin 16′ at about 80° C. in a state where points of the die 21 corresponding to the vertexes of expected condenser lenses 16c substantially coincide with the centers of the respective pixels.

The hardening temperature is set to about 80° C. because the heat-resistant temperature of the organic compound forming the organic EL layer 13 is in general about 100° C.

Subsequently, referring to FIG. 2E, the die 21 is released from the resin 16′ that has been hardened.

Thus, the lens member 16 having on the surface thereof the condenser lenses 16c provided in correspondence with the pixels is formed. In this case, the surfaces of adjacent ones of the condenser lenses 16c in combination form a smooth continuous curve. Consequently, the lens member 16 has a surface free of steps and sharp changes in the slope.

If the surface of the lens member 16 has any steps or sharp changes in the slope, source gas used in forming a second protective layer on the lens member 16 is difficult to spread into the corners of the steps or the like, inhibiting the growth of the film. Consequently, the second protective layer may have cracks, losing its sealing function. Therefore, the surface of the die 21 is to be designed and processed appropriately so that the occurrence of such a situation is prevented and the condenser lenses 16c formed with the die 21 have desired condensing characteristics.

Meanwhile, if the thickness of the lens member 16 at each depression between adjacent ones of the condenser lenses 16c are too small, dust such as residues generated in etching may not be fully absorbed, resulting in the generation of pin holes. Therefore, the thickness of the lens member 16 at each depression is set to 1 μm at minimum and 50 μm at maximum so that reduction in light quantity due to absorption and entry of light emitted from irrelevant pixels are prevented.

While the process illustrated in FIGS. 2C to 2E is based on a method in which the condenser lenses 16c are directly formed with the die 21, the condenser lenses 16c may alternatively be formed by any of the following methods:

i) a method in which a resin layer having a pattern formed by photolithography or the like is heat-treated and is shaped into the condenser lenses 16c by reflow;

ii) a method in which a photo-curable resin layer having a uniform thickness is exposed to light having an intensity distribution in a planar direction, and the resin layer is developed into the condenser lenses 16c;

iii) a method in which the surface of a resin layer having a uniform thickness is processed into the condenser lenses 16c with an ion beam, an electron beam, a laser, or the like;

iv) a method in which the condenser lenses 16c are formed by self-alignment by providing resin droplets of appropriate amounts onto the individual pixels; and

v) a method in which a resin sheet having the condenser lenses 16c formed thereon in advance is prepared separately from the substrate 10 having the organic EL elements, and the resin sheet and the substrate 10 are aligned with and joined to each other.

The condenser lenses 16c according to the embodiment of the present invention may be either semispherical or semicylindrical. If the condenser lenses 16c are semicylindrical, the condenser lenses 16c particularly exert a condensing function in either the vertical or horizontal direction. The longitudinal ends of the semicylindrical condenser lenses 16c may have semispherical shapes or may form vertical surfaces with respect to the substrate 10.

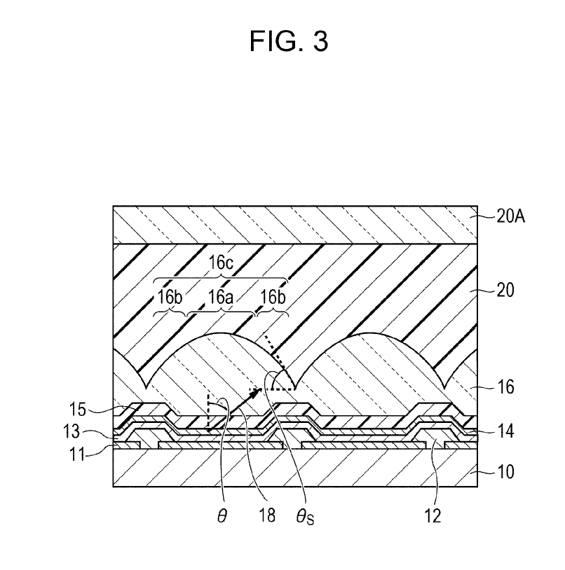

As described above, the lens member 16 may be made of an inorganic material such as silicon nitride. For example, as illustrated in FIG. 3, an inorganic lens member 16 is covered with a resin layer 20 having a smaller refractive index than the inorganic lens member 16 and having a flat surface. The flat surface is provided in the form of a transparent substrate 20A such as a glass substrate. The flat surface extends over the rugged surface of the lens member 16 in such a manner as to be substantially parallel to the luminescent surfaces of the organic EL elements. In such an embodiment also, the beneficial effect produced in the above embodiment of the present invention is produced as long as the lens member 16 satisfies Expressions A and B, i.e., Expression C, at least at one point on the surface thereof. In Expressions A to C, n₁ denotes the refractive index of the inorganic lens member 16, and n₂ denotes the refractive index of the resin layer 20 provided on the inorganic lens member 16. In the embodiment illustrated in FIG. 3, the light 18 transmitted through the resin layer 20 is refracted at the entry into the transparent substrate 20A. However, since the resin layer 20 and the transparent substrate 20A have flat surfaces, the angle of radiation of the light 18 to be outputted from the transparent substrate 20A into the air is determined by the relationship between the refractive indices of the lens member 16 and the resin layer 20, regardless of the refractive index of the transparent substrate 20A. Furthermore, any layers having flat surfaces may be additionally provided on the transparent substrate 20A.

The material forming the inorganic lens member 16 is, for example, silicon nitride or silicon oxynitride and has a refractive index of 1.8 to 2.0. The resin layer 20 provided over the inorganic lens member 16 is made of any of the resin materials named for the lens member 16 according to the above embodiment.

The inorganic lens member 16 is formed as follows. A film of inorganic material is formed on the first protective layer 15 by CVD. A photoresist is applied onto the inorganic film. The photoresist is exposed to light through a photomask and is then developed. Using the developed photoresist as a mask, the inorganic film is dry-etched into a desired shape, whereby the inorganic film forms the lens member 16.

Subsequently, a resin material such as epoxy resin is applied onto the lens member 16, is shaped in such a manner as to form a flat surface, and is hardened. Thus, the lens member 16 and the resin layer 20 overlying the lens member 16 and having a flat surface is provided.

The resin layer 20 having a flat surface may be obtained by providing a flat glass substrate or the like on the resin layer 20.

Another thin resin layer made of a different material from the resin layer 20 having a flat surface may be interposed between the lens member 16 and the resin layer 20 having a flat surface. In such a configuration, if the thin resin layer is thin enough not to affect the refraction of the light 18 at the surface of the lens member 16, the refractive index of the lens member 16 and the refractive index of the resin layer 20 having a flat surface are applied to n₁ and n₂, respectively, in Expressions A and B.

Exemplary applications of the display apparatuses according to the embodiments of the present invention include mobile applications, such as a back monitor of a digital camera and a display of a mobile phone, in which improvement of visibility at high brightness is important. The display apparatuses according to the embodiments of the present invention are expected to consume less power while maintaining the brightness and is therefore also suitable for use indoors.

The present invention is not limited to the above embodiments unless departing from the scope thereof described above, and various changes and modifications can be made thereto.

### EXAMPLES

### Example 1

The substrate 10 illustrated in FIG. 2A was prepared by forming, on a glass substrate, low-temperature polysilicon thin-film transistors (TFT) as pixel circuits (not illustrated) and covering the pixel circuits with an interlayer dielectric film made of SiN and a planarization film made of acrylic resin that were provided in that order. On the substrate 10, an ITO film and an AlNd film were formed with respective thicknesses of 38 nm and 100 nm by sputtering. Subsequently, the ITO film and the AlNd film were patterned into anodes 11 provided in correspondence with the pixels.

The pattern of anodes 11 was spin-coated with acrylic resin. Subsequently, the acrylic resin was lithographically patterned into a partition member 12 having openings (corresponding to the pixels) provided over the respective anodes 11. The pixel pitch was set to 30 μm. The size of a portion of each anode 11 exposed in a corresponding one of the openings was set to 10 μm. The resulting body was ultrasonically cleaned with isopropyl alcohol (IPA), was further cleaned by boiling, and was dried. Furthermore, the resulting body was cleaned with ultraviolet rays and ozone. Subsequently, an organic EL layer 13 was formed on the resulting body by vacuum deposition.

The organic EL layer 13 was formed as follows. First, a hole transport layer having a thickness of 87 nm was formed for each of the pixels.

Subsequently, a red luminescent layer, a green luminescent layer, and a blue luminescent layer were formed for each of the pixels with respective thicknesses of 30 nm, 40 nm, and 25 nm by using a shadow mask.

Subsequently, the pixels were covered with an electron transport layer formed with a thickness of 10 nm by vacuum deposition and were further covered with an electron injection layer formed with a thickness of 40 nm.

Subsequently, the substrate 10 carrying the organic EL layer 13 formed of the above series of layers from the hole transport layer to the electron injection layer was put into a sputtering apparatus while maintaining the vacuum, and a very thin Ag layer and a transparent electrode layer forming a cathode 14 in combination were formed in that order with respective thicknesses of 10 nm and 50 nm. The transparent electrode layer was made of a mixture of indium oxide and zinc oxide.

Subsequently, as illustrated in FIG. 2B, a first protective layer 15 made of silicon nitride was formed by plasma CVD with SiH₄ gas, N₂ gas, and H₂ gas. Subsequently, as illustrated in FIG. 2C, a thermosetting resin material (epoxy resin) having a viscosity of 3000 mPa·s was applied onto the resulting body in a nitrogen atmosphere whose dew point is 60° C. by using a dispenser capable of precision drawing (SHOTmini SL of Musashi Engineering, Inc.).

Before thermally hardening the resin material, the die 21 prepared separately for the formation of the lens member 16 was pressed into the resin material as illustrated in FIG. 2D. In the pressing, the die 21 was positioned such that alignment marks provided on the die 21 and on the substrate 10 coincided with each other. Thus, condenser lenses 16c were formed in correspondence with the pixels. The die 21 had depressions at the same pitch as the pixel pitch. The depressions were coated with a resin based on Teflon (a registered trademark) as a releasing agent. Each of the depressions was formed with a curvature radius of 30 μm in part thereof corresponding to the central portion 16a of the condenser lens 16c and a curvature radius of 100 μm in part thereof corresponding to the peripheral portion 16b of the condenser lens 16c. The height of an array of the condenser lenses 16c was about 4 μm.

Considering the environments in the clean room and in the processing apparatuses, to obtain a flat surface with the resin material even if any foreign substances and the like were present, the smallest thickness, i.e., the thickness at the thinnest part, of the lens member 16 was set to 10 μm.

With the die 21 pressed into the resin material (epoxy resin) as described above, the resulting body was heated at 100° C. for 15 minutes in a vacuum environment, whereby the resin material was hardened. Subsequently, the die 21 was released from the resin material. Thus, the lens member 16 having the condenser lenses 16c as illustrated in FIG. 2E was obtained.

When the brightness of the display apparatus according to Example 1 of the present invention manufactured as described above was measured, the brightness measured straight in the forward direction and the brightness measured at 50 degrees with respect to the forward direction were about 1.5 times higher and about 1.1 times higher, respectively, than those of a display apparatus including no lenses. Moreover, when the display apparatus according to Example 1 was observed in a direction close to the horizontal direction, the image on the display apparatus was visible.

### Example 2

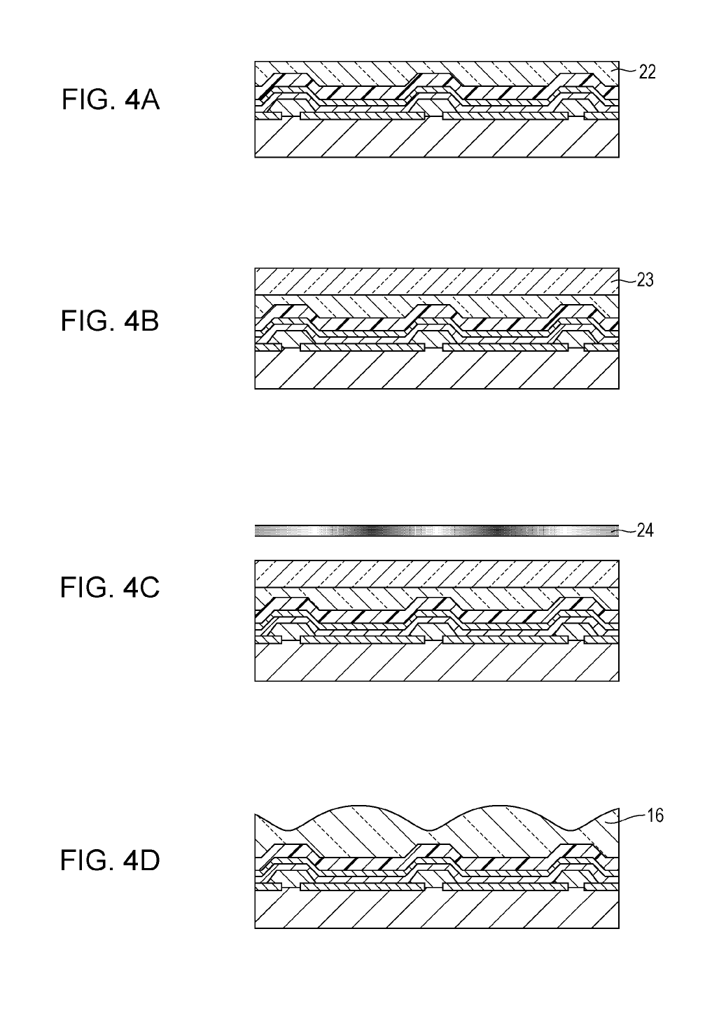

An array of condenser lenses 16c was formed in accordance with a process illustrated in FIGS. 4A to 4D, different from the process employed in Example 1. A process up to the formation of the first protective layer 15 was the same as that in Example 1, and description thereof is therefore omitted. A process of forming a lens member 16 will now be described.

First, referring to FIG. 4A, thermosetting epoxy resin 22 having a viscosity of 3000 mPa·s was applied with a thickness of 10 μm onto the first protective layer 15 in a nitrogen atmosphere whose dew point is 60° C. by using a dispenser capable of precision drawing (SHOTmini SL of Musashi Engineering, Inc.). Then, the epoxy resin 22 was hardened by heating the epoxy resin 22 at 100° C. for 15 minutes in a vacuum environment.

Subsequently, resin 23 of the same kind as the epoxy resin 22 was applied with a thickness of 4 μm onto the epoxy resin 22 as illustrated in FIG. 4B, and the resulting body was exposed to light through a photomask 24 as illustrated in FIG. 4C. The exposure value was set in such a manner as to have a two-dimensional distribution calculated from the shapes of expected condenser lenses 16c. Then, the resin 23 subjected to the exposure was developed. Thus, as illustrated in FIG. 4D, condenser lenses 16c having desired shapes were obtained. The exposure value was controlled in the planar direction by adjusting the transmittance of the photomask 24 in the planar direction. Subsequently, the resin 23 was hardened by heating the resin 23 at 100° C. for 15 minutes in a vacuum environment. In this heat treatment, smoothing of the surface of the lens member 16 was also realized. To have the resin materials absorb any irregularities produced by foreign substances and the like, the smallest thickness, i.e., the thickness at the thinnest part, of the lens member 16 was set to 10 μm.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Applications No. 2011-022852 filed Feb. 4, 2011 and No. 2011-260906 filed Nov. 29, 2011, which are hereby incorporated by reference herein in their entirety.

What is claimed is:

1. A display apparatus comprising:
an organic electroluminescent element;
a protective layer provided in contact with the organic electroluminescent element and configured to cover the organic electroluminescent element; and
a condenser lens provided in contact with the protective layer and on a light output side of the organic electroluminescent element, the condenser lens having a convex surface opposite with respect to the organic electroluminescent element,
wherein, at a point on the convex surface where light emitted from the organic electroluminescent element is incident on the convex surface of the condenser lens, the condenser lens satisfies the following expression:
sin [θ_{S}−Arcsin {(n₁/n₂)×sin(θ_{S}−θ)}]≧1/n₂
where θ denotes an emission angle of the light emitted from the organic electroluminescent element and being incident on the convex surface of the condenser lens, θ_{S} denotes a sloping angle of the convex surface of the condenser lens at a point where the light emitted at the emission angle θ from the organic electroluminescent element is incident, n₁ denotes a refractive index of the condenser lens, and n₂ denotes a refractive index of a medium provided across the condenser lens from the organic electroluminescent element.

2. The display apparatus according to claim 1, wherein the condenser lens includes a central portion and a peripheral portion that have different curvatures, and wherein the condenser lens satisfies the expression at a point in the peripheral portion thereof.

3. The display apparatus according to claim 1, wherein the emission angle θ is 30 degrees or larger.

4. The display apparatus according to claim 1, wherein the medium having the refractive index n₂ has a flat surface on a side thereof remote from the condenser lens.
